(19) United States
(12) Patent Application Publication
(10) Pub. No.: US 2024/0057414 A1
(43) Pub. Date: Feb. 15, 2024

(54) DISPLAY DEVICE AND MANUFACTURING METHOD FOR THE SAME

(71) Applicant: Samsung Display Co., Ltd., Yongin-si (KR)

(72) Inventor: JOO-NYUNG JANG, Yongin-si (KR)

(73) Assignee: Samsung Display Co., Ltd., Yongin-si (KR)

(21) Appl. No.: 18/306,314

(22) Filed: Apr. 25, 2023

(30) Foreign Application Priority Data
Aug. 11, 2022 (KR) 10-2022-0100839

(51) Int. Cl. H10K 59/131; H10K 77/10; H10K 59/12

(52) U.S. Cl. CPC H10K 59/131; H10K 77/111; H10K 59/1201; H10K 2102/311

(57) ABSTRACT

A display device includes a circuit board including multiple circuit pads, a display panel including multiple pad regions and multiple non-pad regions alternately arranged in a first direction, and a conductive adhesive member electrically connecting the circuit board and the display panel and including a photoinitiator. The display panel includes multiple display pads respectively corresponding to the circuit pads, arranged in the first direction, and disposed in the pad regions, respectively, and a base layer disposed under the display pads and having multiple openings. The openings are arranged in the first direction and disposed in the non-pad regions, respectively, and a width of each of the plurality of display pads in the first direction is less than a width of each of the plurality of circuit pads in the first direction.

### CROSS-REFERENCE TO RELATED APPLICATION(S)

This application claims priority to and benefits of Korean Patent Application No. 10-2022-0100839 under 35 U.S.C. § 119, filed on Aug. 11, 2022, in the Korean Intellectual Property Office (KIPO), the entire contents of which are incorporated herein by reference.

### BACKGROUND

### 1. Technical Field

The disclosure herein relates to a display device having improved bonding reliability between a display panel and a circuit board, and a manufacturing method for the same.

### 2. Description of the Related Art

Display devices, such as a television, a monitor, a smart phone, and a tablet computer, which provide an image to a user, include a display panel for displaying the image. As a display panel, various display panels such as a liquid crystal display panel, an organic light-emitting display panel, an electrowetting display panel, and an electrophoretic display panel have been developed.

With the recent technological development of a display device, a display device including a flexible display panel has been developed. The display panel includes a plurality of pixels for displaying an image and a driving circuit for driving the pixels. In order to make the display device thinner, pixels may be disposed in a display region of the display panel, and a circuit board having driving circuits mounted thereon may be connected to a non-display region of the display panel.

### SUMMARY

The disclosure provides a display device having improved bonding reliability and a method for manufacturing a display device with improved bonding reliability.

An embodiment of the disclosure provides a display device that may include a circuit board including a plurality of circuit pads, a display panel including a plurality of pad regions and a plurality of non-pad regions, each of the plurality of pad regions and each of the plurality of non-pad regions alternately arranged in a first direction, and a conductive adhesive member electrically connecting the circuit board and the display panel and including a photoinitiator. The display panel may include a plurality of display pads respectively corresponding to the plurality of circuit pads, arranged in the first direction, and disposed in the plurality of pad regions, respectively, and a base layer disposed under the plurality of display pads and having a plurality of openings. The plurality of openings may be arranged in the first direction and disposed in the plurality of non-pad regions, respectively, and a width of each of the plurality of display pads in the first direction may be less than a width of each of the plurality of circuit pads in the first direction.

In an embodiment, the plurality of display pads may entirely overlap the plurality of pad regions in a plan view, respectively, and the plurality of openings may entirely overlap the plurality of non-pad regions in a plan view, respectively.

In an embodiment, a width of each of the plurality of display pads in a second direction intersecting the first direction and a width of each of the plurality of openings in the second direction may be same, and the plurality of display pads may be spaced apart from each other in a plan view. In an embodiment, the base layer may include a flexible material.

In an embodiment, the base layer may include a first insulating layer disposed under the plurality of display pads and a first base film disposed under the first insulating layer, the first insulating layer may be disposed in the plurality of pad regions and the plurality of non-pad regions, the first base film may include first openings disposed in each of the plurality of non-pad regions, and the plurality of openings may include the first openings. In an embodiment, the first base film may include a polyimide (PI).

In an embodiment, the base layer may further include a second insulating layer disposed under the first base film and a second base film disposed under the second insulating layer, the second insulating layer may be disposed in the plurality of pad regions and the plurality of non-pad regions, the second base film may include second openings corresponding to the first openings, and the plurality of openings may include the second openings.

In an embodiment, the display panel may further include signal lines respectively electrically connected to the display pads, and the signal lines may be spaced apart from the plurality of openings in a plan view.

In an embodiment, the circuit board may further include non-conductive adhesive members disposed between the plurality of circuit pads, and each of the non-conductive adhesive members may include a photoinitiator.

In an embodiment of the disclosure, a display device may include a display panel including a first pad region, a second pad region, and a first non-pad region extending from the first pad region in a first direction and defined between the first pad region and the second pad region, a circuit board including a first circuit pad overlapping the first pad region and a second circuit pad overlapping the second pad region in a plan view, and a conductive adhesive member electrically connecting the circuit board and the display panel and including a photoinitiator. The display panel may include a first display pad disposed in the first pad region and corresponding to the first circuit pad, a second display pad disposed in the second pad region, corresponding to the second circuit pad, and spaced apart from the first display pad in a plan view, a first base part disposed under the first display pad in the first pad region, and a second base part disposed under the second display pad in the second pad region and spaced apart from the first base part in a plan view. A width of each of the first and second display pads in the first direction may be less than a width of each of the first and second circuit pads in the first direction.

In an embodiment, a width of each of the first and second base parts in the first direction may be less than a width of each of the first and second circuit pads in the first direction.

In an embodiment of the disclosure, a method of manufacturing a display device, the method may include providing a circuit board including circuit pads, providing a display panel including a base layer having an opening and display pads, providing a conductive adhesive member between the circuit board and the display panel, and curing the conductive adhesive member by irradiating light to a lower portion of the display panel. The display pads may be electrically connected to the circuit pads. The display pads may be disposed in a pad region, and the opening may be disposed in a non-pad region adjacent to the pad region. In an embodiment of the disclosure, the light may be in a ultraviolet region.

In an embodiment of the disclosure, the conductive adhesive member may include a photoinitiator.

In an embodiment of the disclosure, the method may further include providing a non-conductive adhesive member between the circuit pads. The curing of the conductive adhesive member may include curing the non-conductive adhesive member.

In an embodiment of the disclosure, the conductive adhesive member may include a pad adhesive part overlapping the pad region and a non-pad adhesive part overlapping the non-pad region in a plan view, and the curing of the conductive adhesive member may include curing the pad adhesive part and the non-pad adhesive part. In an embodiment of the disclosure, the pad adhesive part may be cured by diffracted or reflected light.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to an embodiment of the disclosure;

FIGS. 2A and 2B are exploded perspective views of a display device according to an embodiment of the disclosure;

FIG. 3 is a schematic cross-sectional view of a display module according to an embodiment of the disclosure;

FIG. 4 is a plan view of a display panel according to an embodiment of the disclosure;

FIG. 5 is a schematic cross-sectional view of a display panel according to an embodiment of the disclosure;

FIG. 6 is an exploded perspective view of a portion of a display device according to an embodiment of the disclosure;

FIGS. 7A and 7B are perspective views illustrating a portion of a display panel according to an embodiment of the disclosure;

FIGS. 8A to 8C are schematic cross-sectional views illustrating a portion of a display panel according to an embodiment of the disclosure;

FIGS. 9A and 9B are schematic cross-sectional views illustrating a portion of a display device according to an embodiment of the disclosure;

FIG. 10 is a flowchart illustrating a method of manufacturing a display device according to an embodiment of the disclosure;

FIGS. 11A to 11D are schematic cross-sectional views illustrating some operations in a method of manufacturing a display device according to an embodiment of the disclosure; and

FIGS. 12A and 12B are schematic cross-sectional views illustrating some operations in a method of manufacturing a display device according to another embodiment of the disclosure.

### DETAILED DESCRIPTION OF THE EMBODIMENTS

Hereinafter, embodiments of the disclosure will be described with reference to the drawings. In this specification, when an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like numbers or symbols refer to like elements throughout. Also, in the drawings, the thicknesses, ratios, and dimensions of the elements are exaggerated for effective description of the technical contents. The term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

Spatially relative terms, such as “beneath”, “below”, “under”, “lower”, “above”, “upper”, “over”, “higher”, “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below”, for example, can encompass both an orientation of above and below. Furthermore, the apparatus may be otherwise oriented (e.g., rotated 90 degrees or at other orientations), and, as such, the spatially relative descriptors used herein interpreted accordingly.

It will be understood that the term “includes” or “comprises”, when used in this specification, specifies the presence of stated features, numbers, steps, operations, elements, components, or a combination thereof, but does not preclude the presence or addition of one or more other features, numbers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display device according to an embodiment of the disclosure and a manufacturing method for the same will be described.

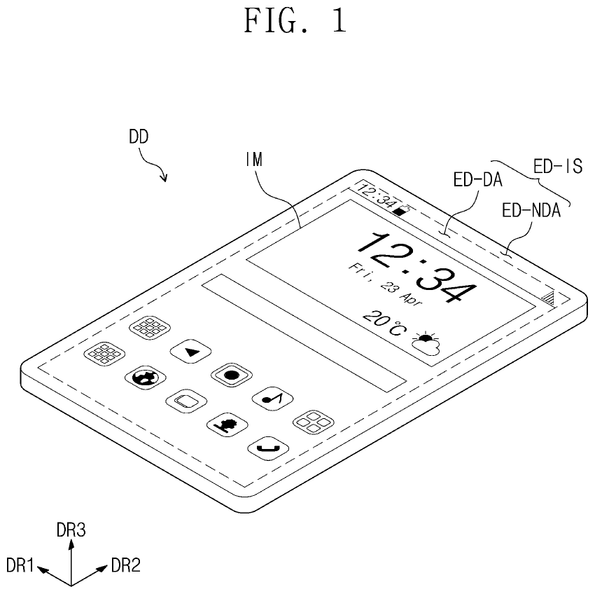

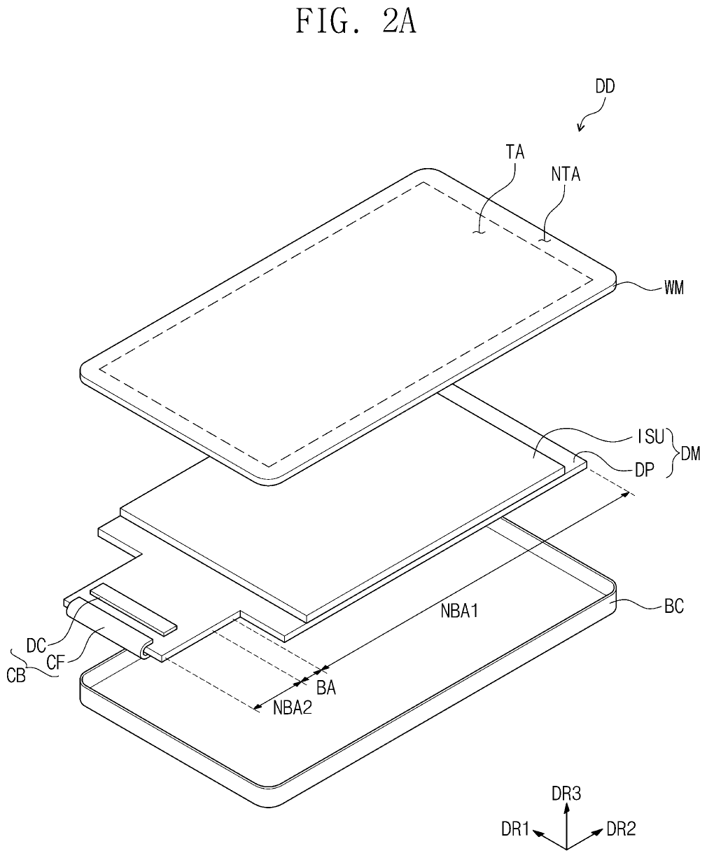

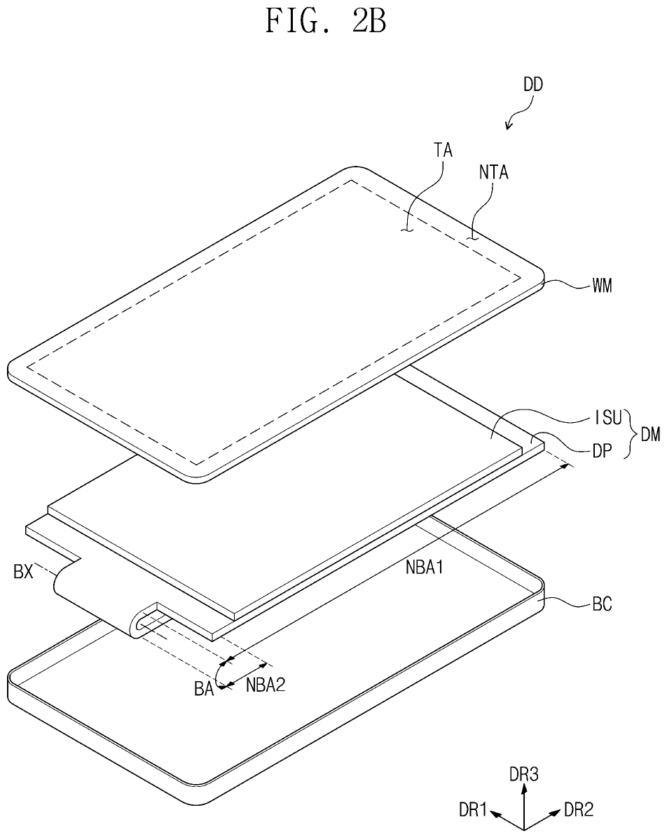

FIG. 1 is a perspective view of a display device according to an embodiment of the disclosure. FIGS. 2A and 2B are exploded perspective views of a display device according to an embodiment of the disclosure. FIG. 2B illustrates a state in which a display panel DP of a display device DD is bent. In this specification, a mobile phone terminal is illustrated as an example of the display device DD. The display device DD according to an embodiment of the disclosure may be applicable to large-sized electronic apparatuses such as television sets and monitors, but also small- and medium-sized electronic apparatuses such as a tablet computer, a car navigation system, a game machine, and a smart watch.

Referring to FIG. 1, the display device DD may display an image IM through a display surface ED-IS. Application icons are illustrated as an example of the image IM. The display surface ED-IS may be parallel to a plane defined by a first direction DR1 and a second direction DR2. A normal direction of the display surface ED-IS, for example, a thickness direction of the display device DD, may be a third direction DR3.

The display surface ED-IS may include a display region ED-DA on which an image IM is displayed and a non-display region ED-NDA adjacent to the display region ED-DA. The non-display region ED-NDA may be a region on which an image is not displayed. However, an embodiment of the disclosure is not limited thereto, and the non-display region ED-NDA may be adjacent to a side of the display region ED-DA or may be omitted.

In this specification, the wording “in a plan view” or “when viewed in a plan view” may mean being viewed in the third direction DR3. A front surface (or a top surface) and a rear surface (or a bottom surface) of each layer or each unit to be described below are distinguished based on the third direction DR3. However, the combination of the first to third directions DR1, DR2, and DR3 may be changed to another combination.

Referring to FIGS. 2A and 2B, the display device DD may include a window WM, a display module DM, and an accommodation member BC.

The window WM may be disposed on the display module DM and may transmit an image provided from the display module DM to the outside. The window WM may include a transmission region TA and a non-transmission region NTA. The transmission region TA may overlap the display region ED-DA illustrated in FIG. 1 in a plan view and may have a shape corresponding to the display region ED-DA. The window WM may include a base layer and functional layers disposed on the base layer. The functional layers may include a protective layer, an anti-fingerprint layer, and the like. The base layer of the window WM may be made of glass, sapphire, or plastic. The base layer of the window WM may include an optically transparent insulating material. For example, the base layer of the window WM may include glass or plastic. The base layer of the window WM may have a multi-layer structure or a single-layer structure. For example, the base layer of the window WM may include multiple plastic films which are bonded by an adhesive, or a glass substrate and a plastic film which are bonded to each other by an adhesive.

The non-transmission region NTA may overlap the non-display region ED-NDA in a plan view and may have a shape corresponding to the non-display region ED-NDA. The non-transmission region NTA may be a region having a relatively lower light transmittance than the transmission region TA. The non-transmission region NTA may be defined by arranging the bezel pattern in a partial region of the base layer of the window WM, and a region where the bezel pattern is not arranged may be defined as the transmission region TA. However, the technical idea of the disclosure is not limited thereto, and the non-transmission region NTA may be omitted.

Although not illustrated, an anti-reflection layer may be disposed between the window WM and the display module DM. The anti-reflection layer may reduce the reflectance of external light which is incident from the outside of the display device DD. The anti-reflection layer may include color filters. The color filters may have an arrangement. For example, the color filters may be arranged in consideration of emission colors of pixels included in the display panel DP, which will be described below. The anti-reflection layer may include a black matrix adjacent to the color filters.

According to an embodiment of the disclosure, the display module DM may include a display panel DP and an input sensor ISU.

The display panel DP may be a liquid crystal display panel, an electrophoretic display panel, a microelectromechanical system (MEMS) display panel, an electrowetting display panel, an organic light-emitting display panel, an inorganic light-emitting display panel, or a quantum dot light-emitting display panel, but is not particularly limited. Hereinafter, the display panel DP is described as an organic light-emitting display panel.

The display panel DP may include a bending region BA, and a first non-bending region NBA1 and a second non-bending region NBA2 which are spaced apart from each other in the second direction DR2, and the bending region BA may be disposed between the first non-bending region NBA1 and the second non-bending region NBA2.

The bending region BA may be defined as a region in which the display panel DP is bent along the virtual bending axis BX extending in the first direction DR1. The first non-bending region NBA1 may be a region overlapping the transmission region TA, and the second non-bending region NBA2 may be a region to which a printed circuit board CF is connected. In case that the bending region BA is bent with respect to the bending axis BX, the bending region BA may be bent toward the rear surface of the display panel DP and the printed circuit board CF and a driving chip DC may be disposed under the rear surface of the display panel DP.

Although not illustrated, additional components for compensating for a step, caused by the bending region BA, between the printed circuit board CF and the rear surface of the display panel DP may be disposed.

According to an embodiment, in the second direction DR2, the width of the first non-bending region NBA1 may be greater than the widths of the bending region BA and the second non-bending region NBA2. However, an embodiment of the disclosure is not limited thereto. The bending region BA may have a shape such that the width thereof in the second direction DR2 becomes smaller from the first non-bending region NBA1 toward the second non-bending region NBA2, but the disclosure is not limited to any one embodiment.

The input sensor ISU may include a capacitive sensor, an optical sensor, an ultrasonic sensor, or an electromagnetic induction sensor. The input sensor ISU may be formed on the display panel DP through a continuous process, or may be separately manufactured and attached to the upper side of the display panel DP through an adhesive layer, but is not limited to any one embodiment.

The display module DM may include a circuit board CB. The circuit board CB may include a driving chip DC and a printed circuit board CF. Although FIG. 2A illustrates an embodiment in which the driving chip DC is mounted on the display panel DP, an embodiment of the disclosure is not limited thereto. The driving chip DC may generate a driving signal necessary for the operation of the display panel DP on the basis of the control signal transmitted from the printed circuit board CF. As a portion of the display panel DP is bent as illustrated in FIG. 2B, the printed circuit board CF electrically bonded to the display panel DP may be disposed on the rear surface of the display panel DP.

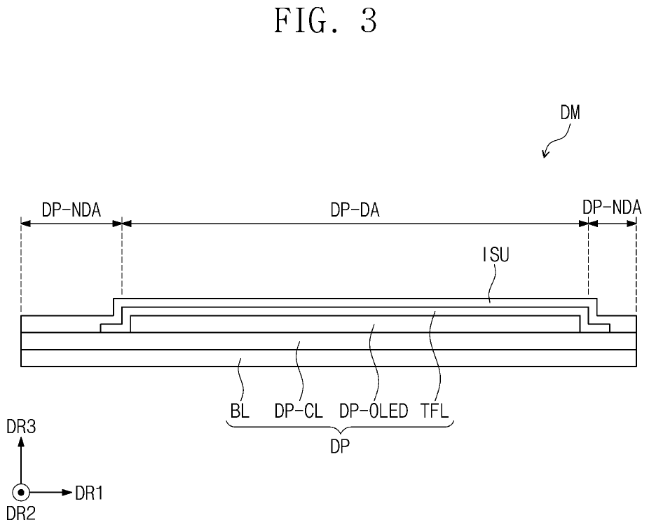

The accommodation member BC may accommodate the display module DM and may be coupled to the window WM. The printed circuit board CF may be disposed on an end of the display panel DP and may be electrically connected to the circuit element layer DP-CL (shown in FIG. 3). Although not illustrated, the display device DD may further include a main board, electronic modules mounted on the main board, a camera module, a power module, and the like.

Although a mobile phone terminal has been described as an example of the display device DD, in this specification, any configuration may be used as long as including two or more electrically bonded electronic components. The display panel DP and the driving chip DC mounted on the display panel DP respectively correspond to different electronic components, and the display device DD may be configured with these components only, but the disclosure is not limited thereto.

In an embodiment, the display device DD may be configured with the display panel DP and the printed circuit board CF connected to the display panel DP only, and the display device DD may be configured with a main board and an electronic module mounted on the main board only. Hereinafter, the display device DD according to an embodiment of the disclosure will be described focusing on a bonding structure of the display panel DP and the driving chip DC mounted on the display panel DP.

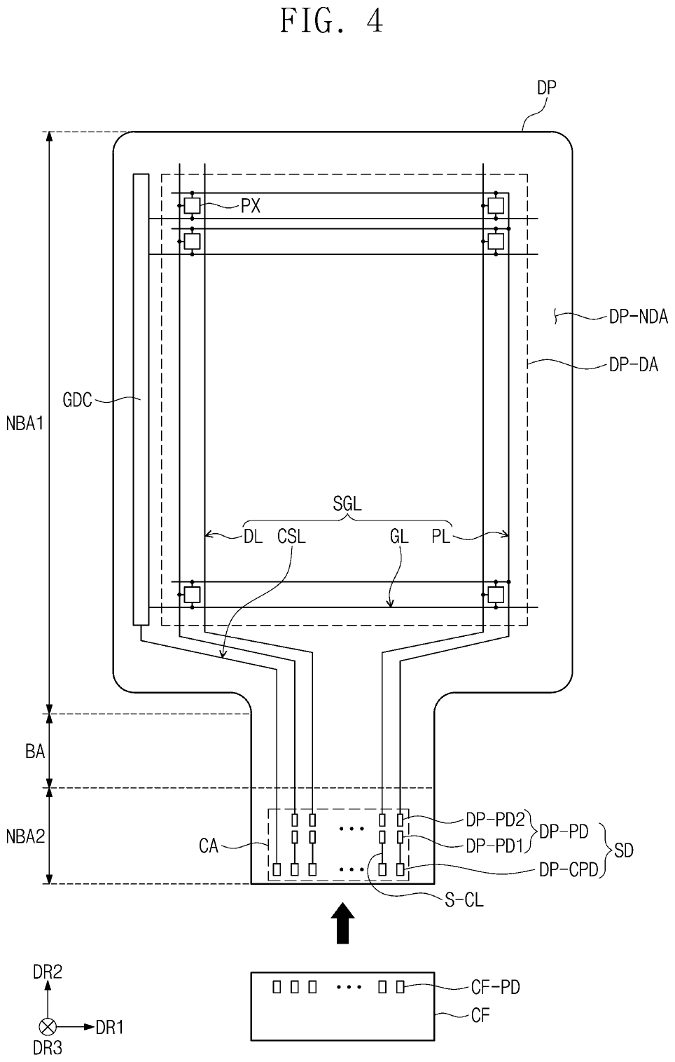

FIG. 3 is a schematic cross-sectional view of a display module according to an embodiment of the disclosure. FIG. 4 is a plan view of a display panel illustrating components of a display module according to an embodiment of the disclosure.

Referring to FIG. 3, the display panel DP may include a base layer BL, a circuit element layer DP-CL disposed on the base layer BL, a display element layer DP-OLED, and an upper insulating layer TFL. The input sensor ISU may be disposed on the upper insulating layer TFL.

The display panel DP may include a display region DP-DA and a non-display region DP-NDA. The display region DP-DA of the display panel DP may correspond to the display region ED-DA illustrated in FIG. 2A or the transmission region TA illustrated in FIG. 2A, and the non-display region DP-NDA may correspond to the non-display region ED-NDA illustrated in FIG. 1 or the non-transmission region NTA illustrated in FIG. 2A.

The base layer BL may include at least one plastic film. The base layer BL may be a flexible substrate and may include a plastic substrate, a glass substrate, a metal substrate, or an organic/inorganic composite material substrate.

The circuit element layer DP-CL may include at least one intermediate insulating layer and a circuit element. The intermediate insulating layer may include at least one intermediate inorganic layer and at least one intermediate organic layer. The circuit element may include signal lines, a driving circuit of a pixel, and the like.

The display element layer DP-OLED may include multiple organic light-emitting diodes. The display element layer DP-OLED may also include an organic layer such as a pixel defining film.

The upper insulating layer TFL may seal the display element layer DP-OLED. The upper insulating layer TFL may be disposed on the display element layer DP-OLED. The upper insulating layer TFL may overlap the display region DP-DA and the non-display region DP-NDA in a plan view. The upper insulating layer TFL may overlap at least a portion of the non-display region DP-NDA. For example, the upper insulating layer TFL may include a thin-film encapsulation layer. The thin-film encapsulation layer may include a stacked structure of an inorganic layer/organic layer/inorganic layer. The upper insulating layer TFL may protect the display element layer DP-OLED from foreign substances such as moisture, oxygen, and dust particles. However, the disclosure is not limited thereto, and the upper insulating layer TFL may include an additional insulating layer other than the thin-film encapsulation layer. For example, the upper insulating layer may include an insulating layer for controlling the refractive index.

In an embodiment of the disclosure, an encapsulation substrate may be provided in place of the upper insulating layer TFL. The encapsulation substrate may face the base layer BL, and a circuit element layer DP-CL and a display element layer DP-OLED may be disposed between the encapsulation substrate and the substrate.

The input sensor ISU may be directly disposed on the display panel DP. In the disclosure, the wording “component A is disposed directly on component B” may indicate that the adhesive layer is not disposed between component A and component B. In this embodiment, the input sensor ISU may be manufactured together with the display panel DP through a continuous process. However, the disclosure is not limited thereto, and the input sensor ISU may be provided as an individual panel and may be coupled to the display panel DP by an adhesive layer. In another embodiment, the input sensor ISU may be omitted.

Referring to FIG. 4, the display panel DP may include multiple pixels PX, a gate driving circuit GDC, multiple signal lines SGL, and multiple display pads DP-PD and DP-CPD.

The pixels PX may be disposed in the display region DP-DA. Each of the pixels PX may include an organic light-emitting diode and a pixel driving circuit connected thereto. The gate driving circuit GDC and the signal lines SGL may be disposed in the circuit element layer DP-CL illustrated in FIG. 3.

The gate driving circuit GDC may sequentially output gate signals to the gate lines GL. The gate driving circuit GDC may include multiple thin-film transistors which are formed through a same process as that for the driving circuit of the pixels PX, such as a low temperature polycrystalline silicon (LTPS) process or a low temperature polycrystalline oxide (LTPO) process. The display panel DP may include another driving circuit that provides an emission control signal to the pixels PX.

The signal lines SGL may include gate lines GL, data lines DL, a power line PL, and a control signal line CSL. Each of the gate lines GL may be connected to the corresponding pixel PX among the pixels PX, and each of the data lines DL may be connected to the corresponding pixel PX among the pixels PX. The power line PL may be connected to the pixels PX. The control signal line CSL may provide control signals to the scan driving circuit.

The signal lines SGL may be disposed in the display region DP-DA and the non-display region DP-NDA. Each of the signal lines SGL may include a pad part and a line part. The line part may be disposed in the display region DP-DA and the non-display region DP-NDA. The pad part may be connected to an end of the line part. The pad part may be disposed in a pad region to be described below.

The display panel DP may include multiple display pads SD. Each of the display pads SD may be disposed to be spaced apart from each other by a distance. The display pads SD according to an embodiment may be disposed in the second non-bending region NBA2. The display pads SD may be disposed in a mounting region CA of the second non-bending region NBA2. The mounting region CA may be defined as a region, in which the display pads SD are disposed, among the second non-bending region NBA2.

The display pads SD may include first pads DP-PD and second pads DP-CPD. The first pads DP-PD may be disposed in the second non-bending region NBA2. The first pads DP-PD may be disposed in the mounting region CA. The driving chip DC (see FIG. 2A) may be mounted on the second non-bending region NBA2. The first pads DP-PD may be electrically connected to the driving chip DC and transmit electrical signals received from the driving chip DC to the signal lines SGL.

The first pads DP-PD may include first row pads DP-PD1 arranged in the first direction DR1 and second row pads DP-PD2 which are spaced apart from the first row pads DP-PD1 in the second direction DR2 and are arranged in the first direction DR1. However, the disclosure is not limited thereto, and the first pads DP-PD may be arranged in one row along the first direction DR1 or in three or more rows.

The second pads DP-CPD may be disposed in the mounting region CA. The second pads DP-CPD may be arranged in the first direction DR1. The first pads DP-PD and the second pads DP-CPD may be connected through bridge signal lines S-CL.

The second pads DP-CPD may also include row pads arranged in the first direction DR1 like the first pads DP-PD. One row pad may include second pads DP-CPD arranged to be spaced apart from each other in the second direction DR2. The second pads DP-CPD arranged in different column may have an arrangement form that overlaps or offset from each other viewed in the first direction DR1, but the disclosure is not limited thereto.

The printed circuit board CF may include substrate pads CF-PD electrically connected to the display panel DP. The substrate pads CF-PD may be arranged in the first direction DR1. Also, in case that the second pads DP-CPD are provided in the form of row pads arranged in the first direction DR1, the substrate pads CF-PD included in the circuit board CF and the second pads DP-CPD may have a same arrangement form, but the disclosure is not limited thereto.

The second pads DP-CPD may be electrically connected to the substrate pads CF-PD included in the printed circuit board CF, and transmit an electrical signal received from the printed circuit board CF to the first pads DP-PD. The printed circuit board CF may be rigid or flexible. For example, in case that the printed circuit board CF is flexible, the printed circuit board may be provided as a flexible printed circuit board.

The printed circuit board CF may include a timing control circuit for controlling the operation of the display panel DP. The timing control circuit may be mounted on the printed circuit board CF in the form of an integrated chip. Although not illustrated, the printed circuit board CF may include an input detection circuit to control the input sensor ISU.

Although FIG. 4 illustrates that the display panel DP has a structure including the first pads DP-PD for mounting the driving chip DC illustrated in FIG. 2A, the disclosure is not limited thereto. The driving chip DC may be mounted on the printed circuit board CF, and the first pads DP-PD may be omitted.

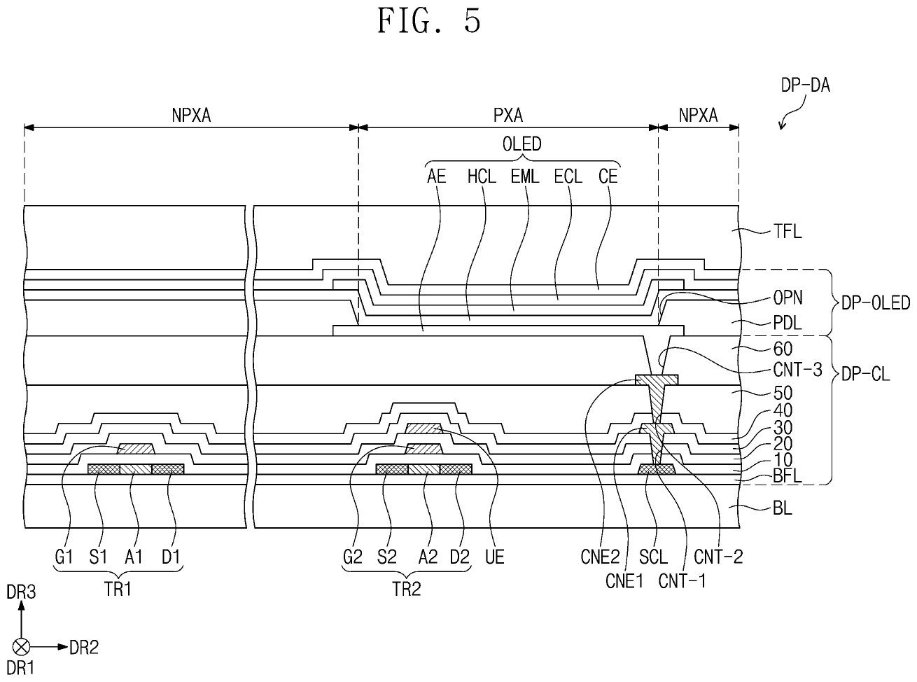

FIG. 5 is a schematic cross-sectional view of a display area of a display panel according to an embodiment of the disclosure.

Referring to FIG. 5, the display region DP-DA may include a light-emitting region PXA and a non-light-emitting region NPXA. Each of the pixels PX may include an organic light-emitting diode and a pixel driving circuit connected thereto. For example, the pixel PX may include a first transistor TR1, a second transistor TR2, and an organic light-emitting diode OLED. Transistors TR1 and TR2 of the pixel driving circuits are shown in FIG. 5.

The display panel DP may include multiple insulating layers, semiconductor patterns, conductive patterns, signal lines, or the like. An insulating layer, a semiconductor layer, and a conductive layer may be formed by coating, deposition, etc., and the insulating layer, the semiconductor layer, and the conductive layer may be selectively patterned through a photolithographic method. The semiconductor pattern, the conductive pattern, the signal line, or the like, which is provided in a circuit element layer DP-CL and a display element layer DP-OLED, may be formed by the methods described above.

The base layer BL may include a synthetic resin film. The base layer BL may have a multi-layered structure. For example, the base layer BL may have a three layer structure including a synthetic resin layer, an inorganic layer, and a synthetic resin layer. For example, the synthetic resin layer may be a polyimide-based resin layer, but the material thereof is not particularly limited. The base layer BL may be a glass substrate, a metal substrate, an organic/inorganic composite material substrate, or the like.

At least one inorganic layer may be disposed on a top surface of the base layer BL. The inorganic layer may be formed as a multi-layer. The multi-layered inorganic layers may constitute a barrier layer and/or a buffer layer. In this embodiment, the display panel DP is illustrated as including a buffer BFL.

A semiconductor pattern may be disposed on the buffer layer BFL. The semiconductor pattern may include polysilicon. However, the disclosure is not limited thereto, and the semiconductor pattern may include amorphous silicon or a metal oxide.

FIG. 5 illustrate only some semiconductor patterns, and semiconductor patterns may be further disposed in another region of the pixel PX in a plan view. The semiconductor patterns may be arranged over pixels according to a specific rule. The semiconductor pattern may have different electrical properties depending on whether the semiconductor pattern is doped or not. The semiconductor pattern may include a first region and a second region. The first region may be doped with an N-type dopant or a P-type dopant. A P-type transistor may include a doped region which is doped with a P-type dopant.

The first region may have higher conductivity than the second region, and substantially serve as an electrode or a signal line. The second region may have a low doping concentration or may be an undoped region, and substantially corresponds to the active (or channel) of the transistor. In other words, a portion of the semiconductor pattern may be an active of the transistor, another portion thereof may be a source or a drain of the transistor, and still another portion thereof may be a connection electrode or a connection signal line.

As illustrated in FIG. 5, a source S1, an active A1, and a drain D1 of a first transistor TR1 may be formed from the semiconductor pattern, and a source S2, an active A2, and a drain D2 of a second transistor TR2 may be formed from the semiconductor pattern.

A portion of a connection signal line SCL formed from the semiconductor pattern is illustrated in FIG. 5. Although not illustrated separately, the connection signal line SCL may be electrically connected to the drain D2 of the second transistor TR2. Another transistor may be disposed between the connection signal line SCL and the drain D2 of the second transistor TR2.

A first insulating layer 10 may be disposed on the buffer layer BFL. The first insulating layer 10 may overlap all the pixels PX (see FIG. 3A) in a plan view and cover the semiconductor pattern. Gates G1 and G2 may be disposed on the first insulating layer 10. The gates G1 and G2 may be a portion of metal pattern. The gates G1 and G2 may overlap the actives A1 and A2 in a plan view. In a process of doping the semiconductor pattern, the gates G1 and G2 may serve as a mask.

A second insulating layer 20 that covers the gates G1 and G2 may be disposed on the first insulating layer 10. The second insulating layer 20 may overlap the pixels PX in common in a plan view. An upper electrode UE may be disposed on the second insulating layer 20. The upper electrode UE may overlap the gate G2 of the second transistor TR2 in a plan view. The upper electrode UE may be a portion of a metal pattern. A portion of the gate G2 and the upper electrode UE overlapping thereof may constitute a capacitor.

A third insulating layer 30 that covers the upper electrode UE may be disposed on the second insulating layer 20. A first connection electrode CNE1 disposed on the third insulating layer 30 may be connected to the connection signal line SCL through a contact hole CNT-1 that passes through the first to third insulating layers 10 to 30.

A fourth insulating layer 40 that covers the first connection electrode CNE1 may be disposed on the third insulating layer 30. The first insulating layer 10 to the fourth insulating layer 40 may be an inorganic layer and/or an organic layer and may have a single- or multi-layered structure.

A fifth insulating layer 50 may be disposed on the fourth insulating layer 40. The fifth insulating layer 50 may be an organic layer. A second connection electrode CNE2 may be disposed on the fifth insulating layer 50. The second connection electrode CNE2 may be connected to the first connection electrode CNE1 through a contact hole CNT-2 that passes through the fourth insulating layer 40 and the fifth insulating layer 50.

A sixth insulating layer 60 that covers the second connection electrode CNE2 may be disposed on the fifth insulating layer 50. The sixth insulating layer 60 may be an organic layer. A first electrode AE may be disposed on the sixth insulating layer 60. The first electrode AE may be connected to the second connection electrode CNE2 through a contact hole CNT-3 that passes through the sixth insulating layer 60.

A pixel opening OPN may be defined in the pixel defining film PDL. The pixel opening OPN of the pixel defining film PDL may expose at least a portion of the first electrode AE. In this embodiment, the light-emitting region PXA may correspond to a partial region of the first electrode AE exposed by the pixel opening OPN.

A hole control layer HCL may be disposed in common in the light-emitting region PXA and the non-light-emitting region NPXA. The hole control layer HCL may include a hole transport layer and may further include a hole injection layer. A light-emitting layer EML may be disposed on the hole control layer HCL. The light-emitting layer EML may be disposed in a region corresponding to the pixel opening OPN. For example, the light-emitting layer EML may be separately formed in each of the pixels. However, the disclosure is not limited thereto, and the light-emitting layer EML may be formed in common in the pixels PX using an open mask.

An electron control layer ECL may be disposed on the light-emitting layer EML. The electron control layer ECL may include an electron transport layer and may further include an electron injection layer. The hole control layer HCL and the electron control layer ECL may be formed in common in the pixels by using an open mask. A second electrode CE may be disposed on the electron control layer ECL. The second electrode CE may have a single integrated shape and may be disposed in common in the pixels PX. The upper insulating layer TFL may be disposed on the second electrode CE. The upper insulating layer TFL may include multiple thin-films.

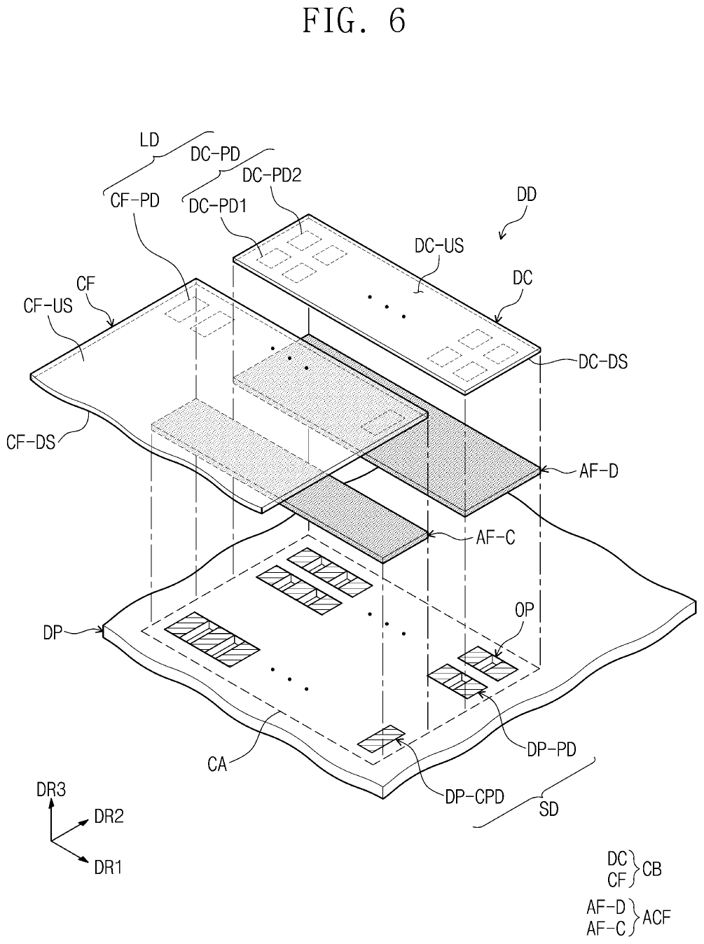

FIG. 6 is an exploded perspective view of a portion of a display device according to an embodiment of the disclosure.

Referring to FIG. 6, the display device DD may include a circuit board CB, a conductive adhesive member ACF, and a display panel DP. FIG. 6 illustrates in which each of the display panel DP, the conductive adhesive member ACF, and the circuit board CB is disassembled and spaced apart from each other for convenience of explanation. However, in the display device according to an embodiment of the disclosure, the display panel DP, the conductive adhesive member ACF, and the circuit board CB may be bonded to each other. For example, in the display device according to an embodiment, at least a portion of the display panel DP may be in contact with the conductive adhesive member ACF, and at least a portion of the circuit board CB may be in contact with the adhesive member ACF.

The circuit board CB may include the printed circuit board CF and the driving chip DC. The circuit board CB may include multiple circuit pads LD, and each of the circuit pads LD may be spaced apart from each other by a distance. The circuit pads LD may include substrate pads CF-PD mounted on the printed circuit board CF and chip pads DC-PD mounted on the driving chip DC.

The printed circuit board CF may include an upper surface CF-US and a lower surface CF-DS. The lower surface CF-DS of the printed circuit board CF may be a surface facing the display panel DP. The substrate pads CF-PD may be disposed on the lower surface CF-DS of the printed circuit board CF, and may be electrically connected to the second pads DP-CPD of the display panel DP, respectively. The substrate pads CF-PD and the second pads DP-CPD may be electrically connected to each other through a first conductive adhesive member AF-C.

The driving chip DC may include an upper surface DC-US and a lower surface DC-DS. The lower surface DC-DS of the driving chip DC may be a surface facing the display panel DP. The driving chip DC may include chip pads DC-PD electrically connected to the first pads DP-PD disposed on the base layer BL. The chip pads DC-PD and the first pads DP-PD may be electrically connected to each other through the second conductive adhesive member AF-D.

The chip pads DC-PD may include first row chip pads DC-PD1 arranged in the first direction DR1 and second row chip pads DC-PD2 which are spaced apart from the first row chip pads DC-PD1 in the second direction DR2 and are arranged in the first direction DR1. The first row chip pads DC-PD1 and the second row chip pads DC-PD2 may have a shape exposed to the outside from the lower surface DC-DS of the driving chip DC. Although it is illustrated in FIG. 6 that the chip pads DC-PD are arranged in two rows, the chip pads DC-PD may be arranged in a single row or multiple rows based on a structure in which the first pads DP-PD are arranged.

The conductive adhesive member ACF may be disposed between the circuit board CB and the display panel DP. The conductive adhesive member ACF may electrically connect the circuit pads LD and the display pads SD. The conductive adhesive member ACF may include a photoinitiator. The conductive adhesive member ACF may include a first conductive adhesive member AF-C which is disposed between the printed circuit board CF and the display panel DP and a second conductive adhesive member AF-D which is disposed between the driving chip DC and the display panel DP.

The display panel DP may include multiple display pads SD and multiple openings OP. The display pads SD and the openings OP may be disposed in the mounting region CA. The display pads SD and the openings OP may be alternately arranged in a direction. The openings OP may be holes defined in the base layer BL.

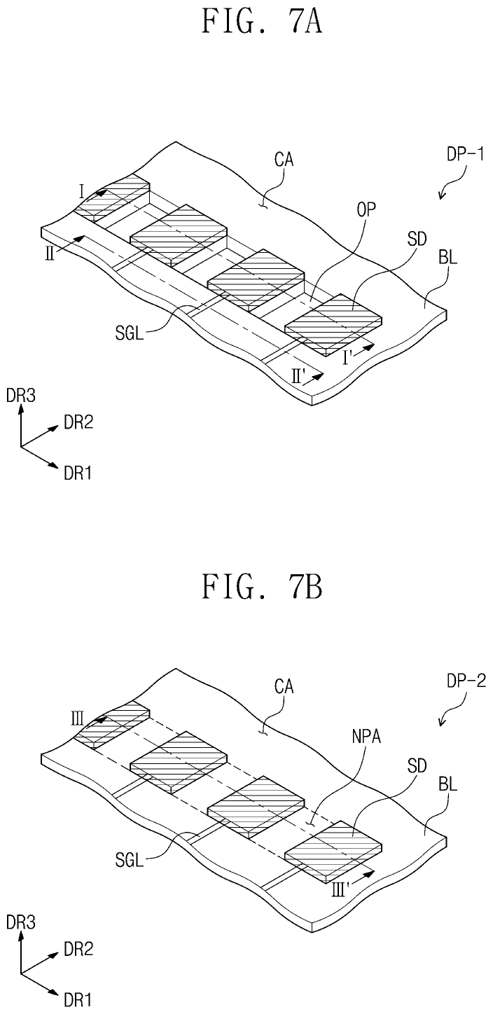

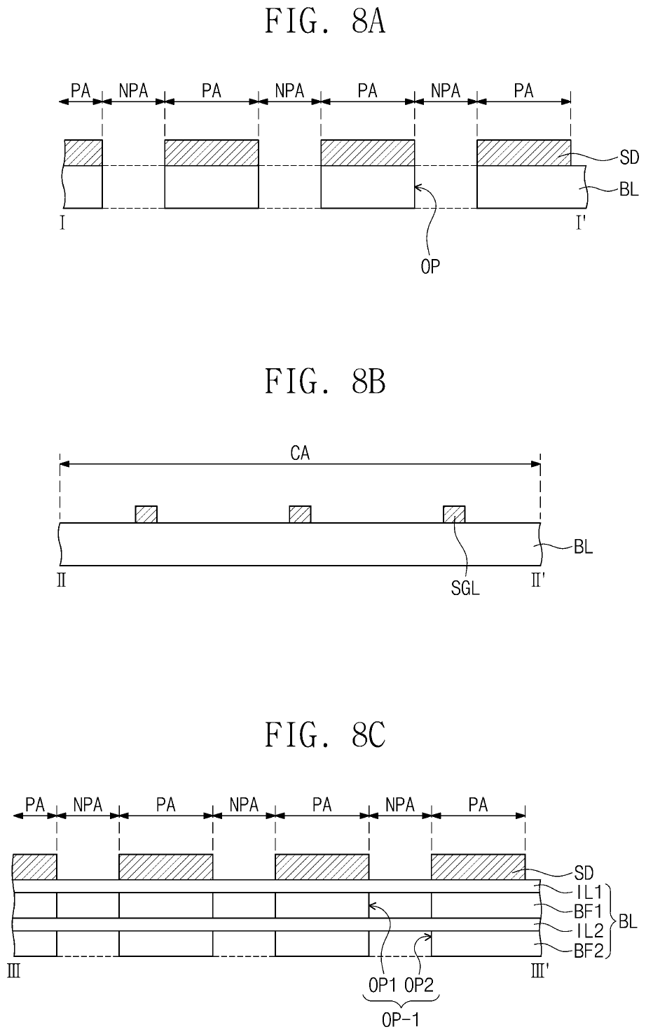

FIGS. 7A and 7B are perspective views illustrating a portion of a display panel according to an embodiment of the disclosure. FIGS. 7A and 7B illustrate different embodiments of the same portion of a display panel. FIGS. 8A to 8C are schematic cross-sectional views illustrating a portion of a display panel according to an embodiment of the disclosure. FIGS. 8A to 8C are schematic cross-sectional views taken along line I-I′ of FIG. 7A, line II-II′ of FIG. 7A, and line III-III′ of FIG. 7B, respectively.

Referring to FIGS. 7A and 8A, the display panel DP-1 may include multiple display pads SD and multiple openings OP that are disposed on the base layer BL in the mounting region CA. The display pads SD illustrated in FIGS. 7A and 8A may represent any one of the above-described first pads DP-PD (see FIG. 6) and second pads DP-CPD (see FIG. 6).

The mounting region CA may include multiple pad regions PA and multiple non-pad regions NPA. The pad regions PA and the non-pad regions NPA may be regions alternately defined in a direction. Each of the non-pad regions NPA may be regions arranged to be spaced apart from each other in the first direction DR1, and the pad regions PA may be disposed between adjacent non-pad regions NPA.

The display pads SD may be arranged on the base layer BL in the pad regions PA, respectively. The openings OP may be defined in the non-pad regions NPA, respectively. The display pads SD may be arranged to entirely overlap the pad regions PA in a plan view, respectively. The openings OP may be defined to entirely overlap the non-pad regions NPA in a plan view, respectively. Accordingly, the base layer BL may include a structure in which the display pad SD and the opening OP are alternately arranged in a direction.

The display pads SD and the openings OP may be alternately arranged in the first direction DR1. Each of the display pads SD may be disposed to be spaced apart from each other by a distance, and each of the openings OP may be disposed to be spaced apart from each other by a distance. A distance between the display pads SD may be substantially the same as a width of each of the openings OP in the first direction DR1, and a distance between the openings OP may be substantially the same as a width of each of the display pads SD in the first direction DR1. In this specification, the term “substantially the same” includes not only the case where the width and thickness of the components are physically exactly the same, but also the case where there is a difference by the error range occurring in the process despite the same design.

A width of each of the display pads SD in the second direction DR2 may be substantially the same as a width of each of the openings OP in the second direction DR2. Accordingly, during manufacturing the display device according to an embodiment of the disclosure, light irradiated to the openings OP may effectively reach the entire surface of the pad region PA. As illustrated in FIGS. 7A and 7B, the display pads SD or the openings OP may have a quadrilateral shape or a cuboid shape extending or shortened along the first direction DR1 or the second direction DR2 in a plan view. However, the disclosure is not limited thereto, and the display pads SD or the openings OP may have a free shape as needed.

Each of the openings OP may be a hole defined in the base layer B L. For example, the base layer BL may be formed so as not to overlap the non-pad regions NPA which are regions where the openings OP are defined. As illustrated in FIG. 8A, in an embodiment, the base layer BL may be not disposed in the openings OP, so that a lower surface of the conductive adhesive member ACF (see FIG. 6) may be exposed. Accordingly, during manufacturing the display device according to an embodiment of the disclosure, light irradiated to the openings OP may be directly irradiated to the lower surface of the conductive adhesive member ACF (see FIG. 6).

Referring to FIGS. 7A, 7B, and 8B, the display panels DP-1 and DP-2 may include signal lines SGL respectively connected to the display pads SD.

The signal lines SGL may be respectively connected to the display pads SD to transfer electrical signals. The signal lines SGL may be disposed on the base layer BL in the mounting region CA. The signal lines SGL may be spaced apart from the openings OP of the base layer BL in a plan view. For example, the openings OP may be arranged in the first direction DR1 with respect to the display pads SD, and the signal lines SGL may have a structure connected in the second direction DR2 intersecting the first direction DR1 with respect to the display pads SD.

Referring to FIGS. 7B and 8C, in an embodiment of the disclosure, the base layer BL of the display panel DP-2 may have a multi-layer structure including insulating layers IL1 and IL2 and base films BF1 and BF2. For example, the insulating layers IL1 and IL2 may include an inorganic material such as silicon oxide. For example, the base films BF1 and BF2 may include a synthetic resin such as a polyimide film. The base films BF1 and BF2 may be transparent or opaque polyimide films as necessary.

The base films BF1 and BF2 may be disposed in the pad region PA and not in the non-pad region NPA. For example, an opening OP-1 may be defined in the non-pad region NPA of the base films BF1 and BF2 among the base layer BL. The insulating layers IL1 and IL2 may be disposed in the pad region PA and the non-pad region NPA. For example, none of the openings may be defined in the insulating layers IL1 and IL2 of the base layer BL. As the insulating layers IL1 and IL2 are disposed in the non-pad region NPA, the lower surface of the conductive adhesive member ACF (see FIG. 6) in the display device may not be exposed. However, since the insulating layers IL1 and IL2 include a light-transmitting material, light irradiated during manufacturing a display device according to an embodiment of the disclosure may be transmitted without blocking the light, and thus the light provided from the lower portion may not be blocked and may reach to the conductive adhesive member ACF (see FIG. 6).

The base layer BL may include a first insulating layer IL1 and a first base film BF1 disposed under the first insulating layer ILL First openings OP1 may be formed in the first base film BF1. The base layer BL may include a second insulating layer IL2 disposed under the first base film BF1 and a second base film BF2 disposed under the second insulating layer IL2. Second openings OP2 corresponding to the first openings OP1 may be formed in the second base film BF2. Since the first openings OP1 and the second openings OP2 are defined to overlap the entire surface of the non-pad region NPA, a width of the first openings OP1 in the first direction DR1 may be substantially the same as a width of the second openings OP2 in the first direction DR1.

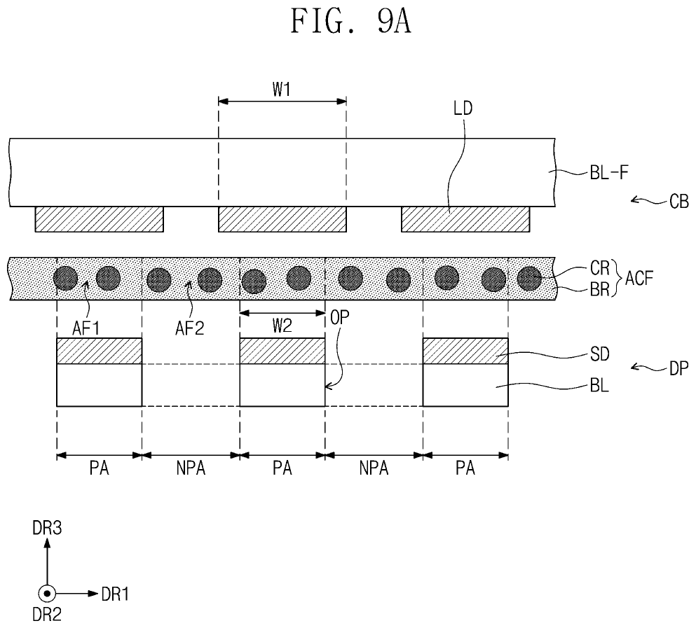

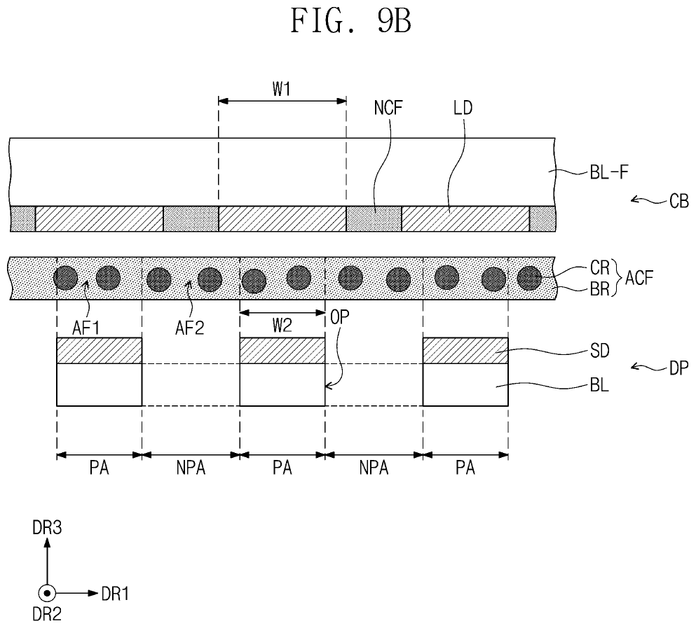

FIGS. 9A and 9B are schematic cross-sectional views illustrating a portion of a display device according to an embodiment of the disclosure. FIG. 9A is an exploded schematic cross-sectional view illustrating a portion where the display panel DP and the circuit board CB are attached through the conductive adhesive member ACF. FIG. 9B is an exploded schematic cross-sectional view illustrating a portion where the display panel DP and the circuit board CB are attached through the conductive adhesive member ACF and a non-conductive adhesive member NCF.

The display device DD may include a display panel DP, a conductive adhesive member ACF, and a circuit board CB. Although FIGS. 9A and 9B schematically illustrate cross-sections in which the display panel DP, the conductive adhesive member ACF, and the circuit board CB are respectively disassembled and spaced apart from each other for convenience of explanation, in the display device according to an embodiment, the display panel DP, the conductive adhesive member ACF, and the circuit board CB may be bonded to each other. For example, in the display device according to an embodiment, at least a portion of the display panel DP may be in contact with the conductive adhesive member ACF, and at least a portion of the circuit board CB may be in contact with the adhesive member ACF. The conductive adhesive member ACF may be disposed between the display panel DP and the circuit board CB and electrically connect the display panel DP and the circuit board CB. The conductive adhesive member ACF may electrically connect the circuit pads LD and the display pads SD.

The conductive adhesive member ACF may include multiple conductive balls CR and an adhesive resin BR in which the conductive balls CR are dispersed. In case that the conductive adhesive member ACF is pressed between the circuit board CB and the display panel DP, the conductive balls CR arranged in the first direction DR1 and the second direction DR2 may electrically connect the circuit pads LD of the circuit board CB and the display pads SD of the display panel DP. The conductive balls CR may be aligned in the first direction DR1 the second direction DR2 in case that the display panel DP and the circuit board CB are electrically connected. The conductive adhesive member ACF may be an anisotropic conductive film (ACF).

The conductive adhesive member ACF may include a photoinitiator. The conductive adhesive member ACF may include a base resin and a photoinitiator. The conductive adhesive member ACF may be a photocurable resin layer. For example, the conductive adhesive member ACF may be formed of an ultraviolet (UV) curable resin. The conductive adhesive member ACF may be activated by light and may be cured by light. For example, the conductive adhesive member ACF may be a resin layer cured by ultraviolet light. The conductive adhesive member ACF may be a member having adhesive strength in case that it is cured by light irradiated during manufacturing the display device according to an embodiment of the disclosure.

The conductive adhesive member ACF may include a pad adhesive part AF1 overlapping the pad region PA and a non-pad adhesive part AF2 overlapping the non-pad region NPA in a plan view. In case that light is irradiated during manufacturing of the display device according to an embodiment of the disclosure, the pad adhesive part AF1 may be cured by reflected or diffracted light and the non-pad adhesive part AF2 may be cured by direct light.

According to an embodiment of the disclosure, referring to FIG. 9B, the circuit board CB may include the circuit base layer BL-F, the circuit pads LD disposed on the circuit base layer BL-F, and the non-conductive adhesive member NCF disposed between the circuit pads LD. The circuit board CB illustrated in FIGS. 9A and 9B may represent any one of the above-described printed circuit board CF (see FIG. 6) and the driving chip DC (see FIG. 6).

The circuit base layer BL-F may include a flexible material. For example, the circuit base layer BL-F may be a polyimide film having a flexible property. The circuit base layer BL-F may be a transparent or opaque polyimide film as necessary.

The circuit pads LD may be disposed on the circuit base layer BL-F. The circuit pads LD illustrated in FIGS. 9A and 9B may represent any one of substrate pads CF-PD (see FIG. 6) mounted on the above-described printed circuit board CF (see FIG. 6) or chip pads DC-PD (see FIG. 6) mounted on the driving chip DC (see FIG. 6).

The circuit pads LD of the circuit board CB may correspond to the display pads SD of the display panel DP. A width W1 of each of the circuit pads LD in the first direction DR1 may be greater than a width W2 of each of the display pads SD in the first direction DR1. For example, each of the circuit pads LD may be disposed to partially overlap each of the pad regions PA of the display panel DP. Since the width W2 of the display pads SD is relatively less than the width W1 of the circuit pads LD, a width of the pad bonding part AF1 in the first direction DR1 may be less than a width W1 of the circuit pads LD in the first direction DR1. Accordingly, in case that light is irradiated during manufacturing the display device according to an embodiment of the disclosure, the amount of light reaching the pad adhesive part AF1 may be increased, and photocurability and adhesion of the pad adhesive part AF1 may be improved, thereby improving the reliability of the display device DD (see FIG. 6).

Referring to FIG. 9B, the non-conductive adhesive member NCF may be disposed in a region between the circuit pads LD. The non-conductive adhesive member NCF may be disposed below the circuit pads LD. The non-conductive adhesive member NCF may have a structure entirely disposed in a region between two circuit pads LD arranged in the first direction DR1. The non-conductive adhesive member NCF may cover side surfaces of each of the circuit pads LD. The non-conductive adhesive member NCF may be a non-conductive film. FIG. 9B illustrates that the non-conductive adhesive member NCF is disposed between the circuit pads LD, but the disclosure is not limited thereto, and in case that the display panel DP and the circuit board CB are bonded, the non-conductive adhesive member NCF may not be disposed. For example, the display panel DP and the circuit board DC may be bonded only by the conductive adhesive member ACF.

The non-conductive adhesive member NCF may be a photocurable resin layer including a photoinitiator. For example, the non-conductive adhesive member NCF may be a UV curable resin layer that is cured by ultraviolet light.

Hereinafter, a method of manufacturing a display device according to an embodiment of the disclosure will be described with reference to the drawings.

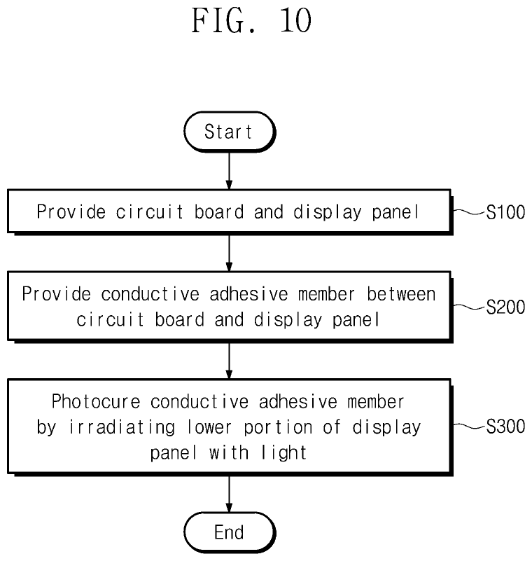

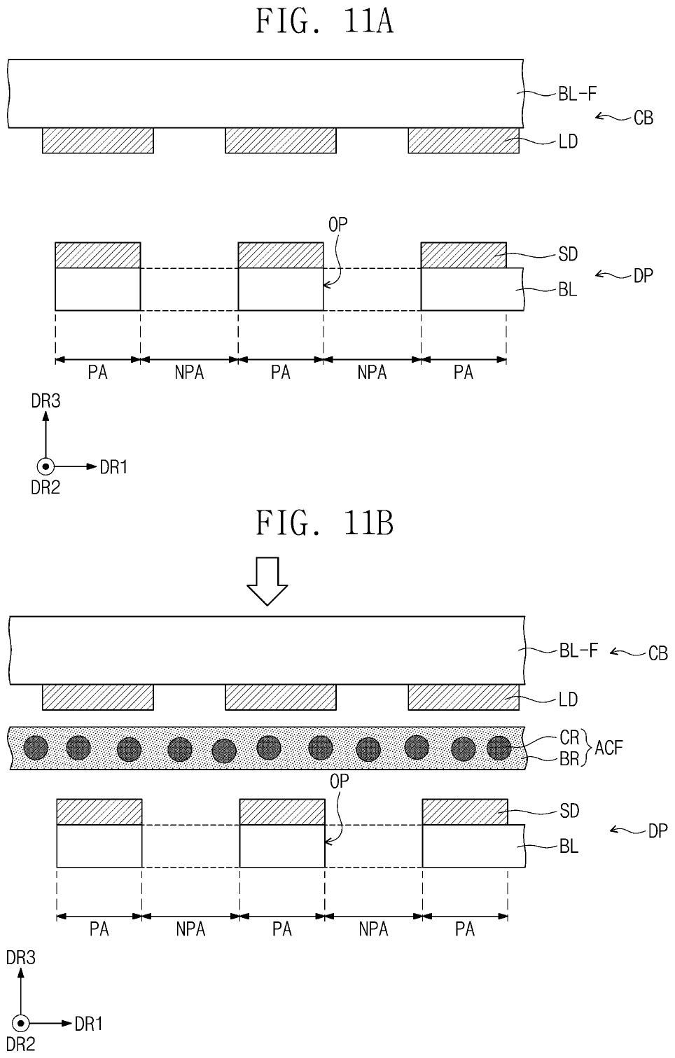

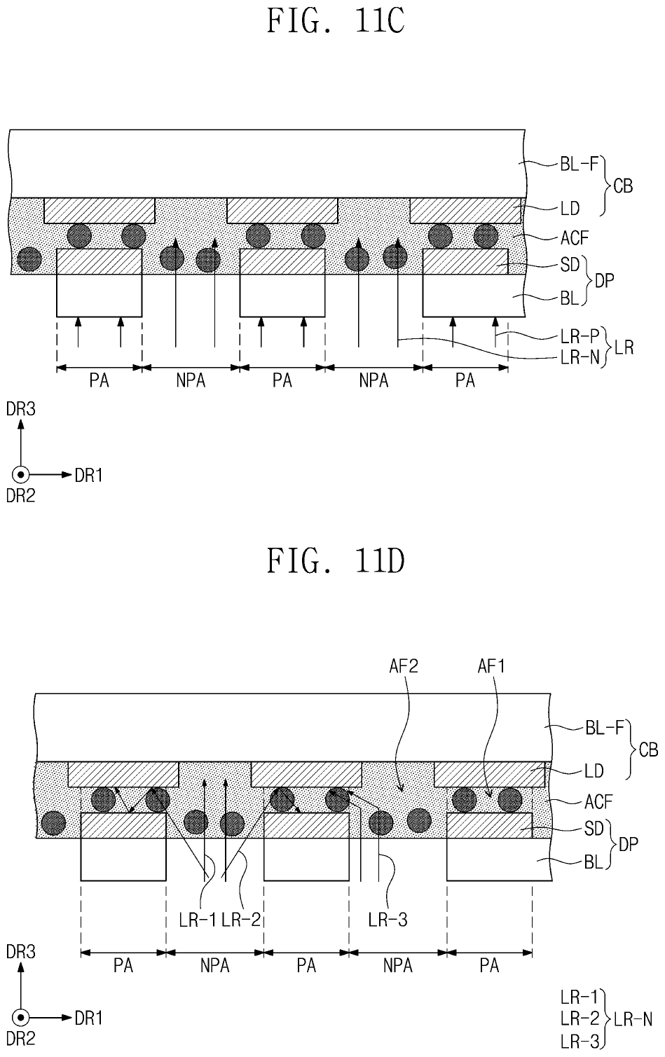

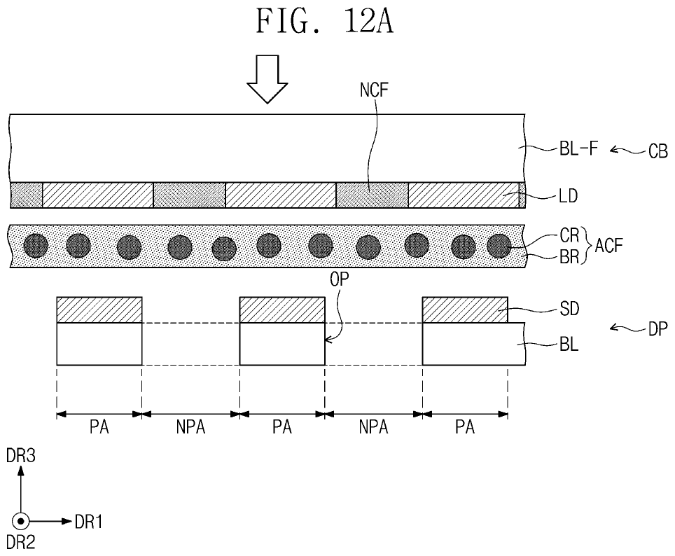

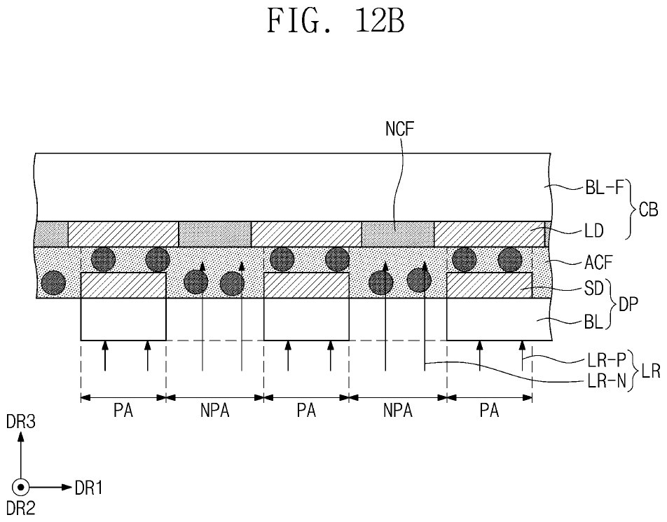

FIG. 10 is a flowchart illustrating a method of manufacturing a display device according to an embodiment of the disclosure. FIGS. 11A to 11D are schematic cross-sectional views illustrating some operations in a method of manufacturing a display device according to an embodiment of the disclosure. FIGS. 12A and 12B are schematic cross-sectional views illustrating some operations in a method of manufacturing a display device according to another embodiment of the disclosure.

As describing the method of manufacturing a display device according to an embodiment, the same reference symbols are given to components that are the same as those described above, and their detailed description will be omitted.

Referring to FIGS. 10, 11A to 11D, 12A and 12B together, a method of manufacturing a display device according to an embodiment of the disclosure may include providing a circuit board and a display panel (S100), providing a conductive adhesive member between a circuit board and a display panel (S200), and photocuring a conductive adhesive member by irradiating a lower portion of a display panel with light (S300).

Referring to FIG. 11A, a method of manufacturing the display device according to an embodiment of the disclosure may include providing a circuit board CB and a display panel DP. The circuit board CB may include circuit pads LD, and the display panel DP may include the display pads SD corresponding to circuit pads SD. Also, the display panel DP may include the base layer BL including the opening OP. The opening OP of the display panel DP may be disposed in the non-pad region NPA, and the display pads SD of the display panel DP may be disposed in the pad region PA.

Referring to FIG. 11B, the method of manufacturing the display device according to an embodiment of the disclosure may include providing a conductive adhesive member ACF between the circuit board CB and the display panel DP. The conductive adhesive member ACF may be a photocurable resin layer including a photoinitiator.

The method of manufacturing the display device according to an embodiment of the disclosure may further include pressing at least one of the circuit board CB and the display panel DP after the providing of the conductive adhesive member ACF and before photocuring the conductive adhesive member ACF. After the pressing, the upper surface of the conductive adhesive member ACF may contact the circuit board CB, and the lower surface of the conductive adhesive member ACF may contact the display panel DP. For example, after the pressing at least one of the circuit board CB and the display panel DP, the circuit board CB and the display panel DP may be temporarily bonded.

Referring to FIG. 11C, the method of manufacturing the display device according to an embodiment of the disclosure may include the photocuring of the conductive adhesive member ACF by irradiating light LR to the lower portion of the display panel DP. The light LR irradiated to the lower portion of the display panel DP may be ultraviolet light. The light LR irradiated to the lower portion of the display panel DP may include blocking light LR-P and transmitted light LR-N. The blocking light LR-P may be light that is reflected from the display pad SD of the pad region PA and is blocked without substantially reaching the conductive adhesive member ACF. The transmitted light LR-N may be light transmitted through the opening OP (see FIG. 11B) of the non-pad region NPA and reached to the conductive adhesive member ACF. The amount of transmitted light LR-N may increase as the distance between the display pads SD in the first direction DR1 decreases. The photocuring of the conductive adhesive member ACF may be photocuring by the transmitted light LR-N. In the method of manufacturing the display device according to an embodiment of the disclosure, by providing the opening OP (see FIG. 11B) in the display panel DP, a portion of the light LR may pass through the display panel DP, and thus the conductive adhesive member ACF may be efficiently cured.

Referring to FIG. 11D, the transmitted light LR-N reaching the conductive adhesive member ACF may include first light LR-1, second light LR-2, and third light LR-3. The first light LR-1 may reach the non-pad adhesive part AF2. The first light LR-1 may be directly irradiated to the non-pad adhesive part AF2 among the transmitted light LR-N. Accordingly, the non-pad adhesive part AF2 may be photocured by the first light LR-1. The second light LR-2 and the third light LR-3 may reach the pad adhesive part AF1. The second light LR-2 may be light reflected from the display pad SD or the circuit pad LD among the transmitted light LR-N. For example, the second light LR-2 may be defined as light in which the transmitted light LR-N is reflected from the display pad SD or the circuit pad LD once or multiple times in the pad region PA. The third light LR-3 may be light diffracted into the pad region PA among the transmitted light LR-N. Accordingly, the pad adhesive part AF1 may be photocured by the second light LR-2 and the third light LR-3. Although not illustrated, the pad adhesive part AF1 may be photocured by light directly irradiated from the transmitted light LR-N. However, as the pad adhesive portion AF1 is cured not only by direct light but also by the second light LR-2 and the third light LR-3, the pad adhesive part AF1 may secure reliable photocurability.

Referring to FIG. 12A, a method of manufacturing the display device according to an embodiment of the disclosure may include providing a circuit board CB including a non-conductive adhesive member NCF and a display panel PD. The non-conductive adhesive member NCF may be provided in a region between the circuit pads LD. The non-conductive adhesive member NCF may be a photocurable resin layer including a photoinitiator. The method of manufacturing the display device according to an embodiment of the disclosure may include pressing at least one of the circuit board CB and the display panel DP after the providing of the circuit board CB and the display panel PD and before the photocuring of the non-conductive adhesive member NCF.

Referring to FIG. 12B, the method of manufacturing the display device according to an embodiment of the disclosure may further include photocuring the non-conductive adhesive member NCF. The light LR irradiated to the lower portion of the display panel DP may be ultraviolet light. The non-conductive adhesive member NCF may be photocured by the transmitted light LR-N. The photocuring of the non-conductive adhesive member NCF may be a single operation that occurs simultaneously with the curing of the conductive adhesive member ACF. For example, the non-conductive adhesive member NCF and the conductive adhesive member ACF may be simultaneously photocured by the transmitted light LR-N.

Although not illustrated, the method of manufacturing the display device according to an embodiment of the disclosure may include providing the circuit board CB including the non-conductive adhesive member NCF and curing the non-conductive adhesive member NCF, and may include the pressing at least one of the display panel DP and the circuit board CB and the curing of the conductive adhesive member ACF. For example, the curing of the non-conductive adhesive member NCF may be performed before the pressing at least one of the display panel DP and the circuit board CB, and the curing of the conductive adhesive member ACF may be performed after the pressing operation.

In a display device according to an embodiment of the disclosure, an opening may be formed in a region between pads of a display panel, so that bonding reliability between the display panel and a circuit board may be improved and process efficiency may be increased. In case that an adhesive member of a photocurable resin layer is used for bonding between the display panel and the circuit board, a light irradiation process may be performed. However, in case that light is irradiated to a region where the pad is disposed, the light may be reflected and may not reach the adhesive member. The display device according to an embodiment of the disclosure may use light transmitted through the opening disposed in the region between pads to cure the adhesive member in the pad region. For example, the adhesive member may be cured using the reflected light and the diffracted light of the light transmitted through the opening. The display device may secure a reliable degree of curing by increasing an amount of reflected or diffracted light by setting the width of the pad of the display panel to be relatively small. During the display device according to an embodiment of the disclosure is manufactured, since the opening is formed in the region between the pads instead of the opening in the pad itself, process convenience may be secured. Accordingly, as the bonding reliability between the display panel and the circuit board is secured, the driving reliability of the display device may be improved.

According to embodiments of the disclosure, since a display device includes a base layer in which multiple openings disposed in a non-pad region of a display panel are defined, the reliability of the photocurability of a photocurable adhesive member disposed between the display panel and the circuit board may be improved, and the efficiency of the display device manufacturing process may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments.

What is claimed is:

1. A display device comprising:
a circuit board including a plurality of circuit pads;
a display panel including a plurality of pad regions and a plurality of non-pad regions, each of the plurality of pad regions and each of the plurality of non-pad regions alternately arranged in a first direction; and
a conductive adhesive member electrically connecting the circuit board and the display panel and including a photoinitiator, wherein
the display panel includes:
a plurality of display pads respectively corresponding to the plurality of circuit pads, arranged in the first direction, and disposed in the plurality of pad regions, respectively; and
a base layer disposed under the plurality of display pads and having a plurality of openings,
the plurality of openings are arranged in the first direction and disposed in the plurality of non-pad regions, respectively, and
a width of each of the plurality of display pads in the first direction is less than a width of each of the plurality of circuit pads in the first direction.

2. The display device of claim 1, wherein
the plurality of display pads entirely overlap the plurality of pad regions in a plan view, respectively, and
the plurality of openings entirely overlap the plurality of non-pad regions in a plan view, respectively.

3. The display device of claim 1, wherein a width of each of the plurality of display pads in a second direction intersecting the first direction and a width of each of the plurality of openings in the second direction are same.

4. The display device of claim 1, wherein the plurality of display pads are spaced apart from each other in a plan view.

5. The display device of claim 1, wherein the base layer comprises a flexible material.

6. The display device of claim 1, wherein
the base layer comprises a first insulating layer disposed under the plurality of display pads and a first base film disposed under the first insulating layer,
the first insulating layer is disposed in the plurality of pad regions and the plurality of non-pad regions,
the first base film includes first openings disposed in each of the plurality of non-pad regions, and
the plurality of openings include the first openings.

7. The display device of claim 6, wherein the first base film comprises a polyimide (PI).

8. The display device of claim 6, wherein
the base layer further comprises a second insulating layer disposed under the first base film and a second base film disposed under the second insulating layer,
the second insulating layer is disposed in the plurality of pad regions and the plurality of non-pad regions,
the second base film includes second openings corresponding to the first openings, and
the plurality of openings include the second openings.

9. The display device of claim 1, wherein the display panel further comprises signal lines respectively electrically connected to the plurality of display pads.

10. The display device of claim 9, wherein the signal lines are spaced apart from the plurality of openings in a plan view.

11. The display device of claim 1, wherein the circuit board further includes non-conductive adhesive members disposed between the plurality of circuit pads.

12. The display device of claim 11, wherein each of the non-conductive adhesive members comprises a photoinitiator.

13. A display device comprising:
a display panel including a first pad region, a second pad region, and a first non-pad region extending from the first pad region in a first direction and defined between the first pad region and the second pad region;
a circuit board including a first circuit pad overlapping the first pad region and a second circuit pad overlapping the second pad region in a plan view; and
a conductive adhesive member electrically connecting the circuit board and the display panel and including a photoinitiator, wherein
the display panel includes:
a first display pad disposed in the first pad region and corresponding to the first circuit pad;
a second display pad disposed in the second pad region, corresponding to the second circuit pad, and spaced apart from the first display pad in a plan view;
a first base part disposed under the first display pad in the first pad region; and
a second base part disposed under the second display pad in the second pad region and spaced apart from the first base part in a plan view, and
a width of each of the first and second display pads in the first direction is less than a width of each of the first and second circuit pads in the first direction.

14. The display device of claim 13, wherein a width of each of the first and second base parts in the first direction is less than a width of each of the first and second circuit pads in the first direction.

15. A method of manufacturing a display device, the method comprising:
providing a circuit board including circuit pads;
providing a display panel including a base layer having an opening and display pads;
providing a conductive adhesive member between the circuit board and the display panel; and
curing the conductive adhesive member by irradiating light to a lower portion of the display panel, wherein
each of the display pads are electrically connected to each of the circuit pads,
the display pads are disposed in a pad region, and
the opening is disposed in a non-pad region adjacent to the pad region.

16. The method of claim 15, wherein the light is in a ultraviolet region.

17. The method of claim 15, wherein the conductive adhesive member comprises a photoinitiator.

18. The method of claim 15, further comprising:
providing a non-conductive adhesive member between the circuit pads, wherein
the curing of the conductive adhesive member comprises curing the non-conductive adhesive member.

19. The method of claim 18, wherein
the conductive adhesive member comprises a pad adhesive part overlapping the pad region and a non-pad adhesive part overlapping the non-pad region in a plan view, and
the curing of the conductive adhesive member comprises curing the pad adhesive part and the non-pad adhesive part.

20. The method of claim 19, wherein the pad adhesive part is cured by diffracted or reflected light.
